(19) United States
(12) Patent Application Publication
(10) Pub. No.: US 2024/0038676 A1
(43) Pub. Date: Feb. 1, 2024

(54) ARRAY SUBSTRATE, PREPARATION METHOD THEREOF, DISPLAY PANEL, AND DISPLAY DEVICE

(71) Applicant: Tianma Advanced Display Technology Institute (Xiamen) Co., Ltd., Xiamen (CN)

(72) Inventor: Sitao HUO, Xiamen (CN)

(73) Assignee: Tianma Advanced Display Technology Institute (Xiamen) Co., Ltd., Xiamen (CN)

(21) Appl. No.: 18/380,305

(22) Filed: Oct. 16, 2023

(30) Foreign Application Priority Data
Jun. 30, 2023 (CN) 202310798779.5

(51) Int. Cl. H01L 23/544; H01L 25/075

(52) U.S. Cl. CPC H01L 23/544; H01L 25/0753; H01L 2223/54426

(57) ABSTRACT

Provided are an array substrate, a preparation method thereof, a display panel, and a display device. The array substrate includes a substrate, an alignment mark, a mark covering layer, and a light-shielding layer. The alignment mark is disposed on a side of the substrate. The mark covering layer is disposed on a side of the alignment mark facing away from the substrate. The mark covering layer at least partially overlaps the alignment mark. The transmittance of the light-shielding layer is less than the transmittance of the mark covering layer. The light-shielding layer is in contact with the mark covering layer and exposes at least a portion of the mark covering layer.

### CROSS-REFERENCE TO RELATED APPLICATION(S)

This application claims priority to Chinese Patent Application No. 202310798779.5 filed Jun. 30, 2023, the disclosure of which is incorporated herein by reference in its entirety.

### TECHNICAL FIELD

The present application relates to the technical field of display devices and, in particular, to an array substrate, a preparation method thereof, a display panel, and a display device.

### BACKGROUND

With the development of science and technology, display panels have developed rapidly. Display panels are widely used in various consumer electronics such as mobile phones, televisions, personal digital assistants, digital cameras, laptops, and desktops and become an indispensable part of people's daily life.

In the preparation process of a display panel, an alignment mark generally needs to be disposed on an array substrate to satisfy the alignment preparation of some layers and improve the preparation accuracy of the display panel. However, the alignment mark is easily shielded, thereby leading to a certain deviation in the preparation of some layers and being disadvantageous to the preparation yield of display panels.

### SUMMARY

Embodiments of the present application provide an array substrate, a preparation method thereof, a display panel, and a display device so as to improve preparation accuracy.

In a first aspect, an embodiment of the present application provides an array substrate. The array substrate includes a substrate, an alignment mark, a mark covering layer, and a light-shielding layer. The alignment mark is disposed on a side of the substrate. The mark covering layer is disposed on a side of the alignment mark facing away from the substrate. The mark covering layer at least partially overlaps the alignment mark. A transmittance of the light-shielding layer is less than a transmittance of the mark covering layer. The light-shielding layer is in contact with the mark covering layer and exposes at least a portion of the mark covering layer.

In a second aspect, an embodiment of the present application provides a display panel. The display panel includes the array substrate in any preceding embodiment.

In a third aspect, an embodiment of the present application provides a display device. The display device includes the display panel in any preceding embodiment.

In a fourth aspect, an embodiment of the present application provides a preparation method of an array substrate. The method includes the steps below.

An alignment mark is formed on a side of a substrate.

A mark covering layer is formed on a side of the alignment mark facing away from the substrate. The mark covering layer at least partially overlaps the alignment mark.

After the mark covering layer is formed, a light-shielding material is coated on the side of the alignment mark facing away from the substrate. The light-shielding material is in contact with the mark covering layer, exposes at least a portion of the mark covering layer, and forms a light-shielding layer.

### BRIEF DESCRIPTION OF DRAWINGS

To illustrate technical solutions in embodiments of the present application more clearly, the drawings used in the description of the embodiments are briefly described below. Those skilled in the art may obtain other drawings based on the drawings described below on the premise that no creative work is done.

FIG. 1 is a sectional diagram of an array substrate according to an embodiment of the present application.

FIG. 2 is a sectional diagram of another array substrate according to an embodiment of the present application.

FIG. 3 is a sectional diagram of another array substrate according to an embodiment of the present application.

FIG. 4 is a sectional diagram of another array substrate according to an embodiment of the present application.

FIG. 5 is a top view of another array substrate according to the embodiments of the present application.

FIG. 6 is a diagram illustrating the relative position relationship between an alignment mark and a mark covering layer in region Q of FIG. 5.

FIG. 7 is a diagram illustrating the relative position relationship between an alignment mark and a mark covering layer in region Q of another array substrate.

FIG. 8 is a sectional diagram of another array substrate according to an embodiment of the present application.

FIG. 9 is a sectional view of a display panel according to an embodiment of the present application.

FIG. 10 is a structural view of a display device according to an embodiment of the present application.

FIG. 11 is a flowchart of a preparation method of an array substrate according to an embodiment of the present application.

FIGS. 12a to 12c are diagrams illustrating the process structure of a preparation method of an array substrate according to an embodiment of the present application.

### REFERENCE LIST

10 substrate
20 alignment mark
30 mark covering layer
40 light-shielding layer
41 opening structure
50 first metal layer
51 first conductive portion
52 second conductive portion
60 light-emitting element
61 first electrode
62 second electrode
M1 first surface
M11 first portion
M12 second portion
M13 third portion
B sidewall
X first direction
Y thickness direction
A1 first region
A2 second region

### DETAILED DESCRIPTION

Features and exemplary embodiments in various aspects of the present application are described hereinafter in detail. To provide a clearer understanding of objects, technical solutions, and advantages of the present application, the present application is further described in detail in conjunction with drawings and embodiments. It is to be understood that the embodiments set forth below are intended to illustrate and not to limit the present application. To those skilled in the art, the present application may be implemented with no need for some of these specific details. The description of the embodiments hereinafter is intended only to provide a better understanding of the present application through examples of the present application.

It is to be noted that in this article, relationship terms such as a first and a second are used merely to distinguish one entity or operation from another. It does not necessarily require or imply any such actual relationship or order between these entities or operations. Furthermore, the term “comprising”, “including” or any other variant thereof is intended to encompass a non-exclusive inclusion so that a process, method, article or device that includes a series of elements not only includes the expressly listed elements but may also include other elements that are not expressly listed or are inherent to such process, method, article or device. In the absence of more restrictions, the elements defined by the statement “including . . . ” do not exclude the presence of additional identical elements in the process, method, article or device that includes the elements.

An alignment mark generally needs to be disposed on an array substrate. Some layers are positioned and prepared by means of the alignment mark. Specifically, the alignment mark is generally disposed in a specific position. When some films are prepared, the alignment mark may be positioned by means of the reflection of light from the alignment mark. On this basis, the specific position of a layer relative to the array substrate can be determined, and then the accurate preparation of the layer may be completed.

However, in the preparation process, the alignment mark is easily shielded by light-shielding materials in some layers. Therefore, when other layers are prepared, it is difficult to determine the specific position of the alignment mark, thereby leading to a certain deviation in the preparation of some layers and being disadvantageous to the preparation yield of display panels.

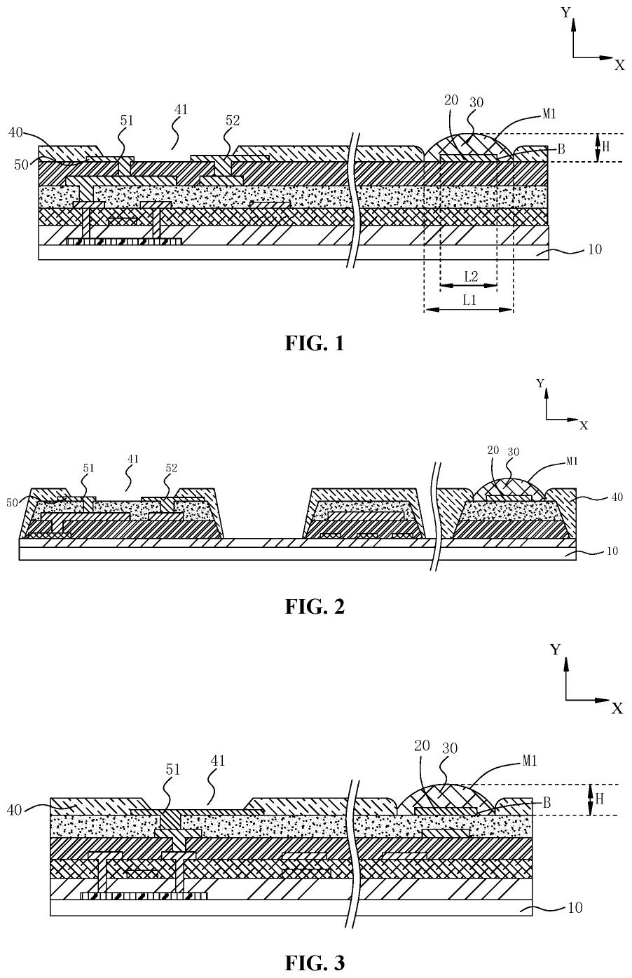

Regarding the preceding problem, in a first aspect, referring to FIGS. 1 and 2, an embodiment of the present application provides an array substrate. The array substrate includes a substrate 10, an alignment mark 20, a mark covering layer 30, and a light-shielding layer 40. The alignment mark 20 is disposed on a side of the substrate 10. The mark covering layer 30 is disposed on a side of the alignment mark 20 facing away from the substrate 10. The mark covering layer 30 at least partially overlaps the alignment mark 20. The transmittance of the light-shielding layer 40 is less than the transmittance of the mark covering layer 30. The light-shielding layer 40 is in contact with the mark covering layer 30 and exposes at least a portion of the mark covering layer 30.

The array substrate according to the embodiment of the present application may be used for forming a display panel. The array substrate is applicable to various display panels. For example, the array substrate may be applicable to a display panel in which a micro light-emitting diode is used as a light-emitting element, with the structure shown in FIG. 1. Alternatively, the array substrate may also be applicable to a light-transmissive display panel, with the structure shown in FIG. 2. Alternatively, the array substrate may also be applicable to a display panel in which an organic light-emitting structure is used as a light-emitting element, with the structure shown in FIG. 3.

The substrate 10 mainly performs a supporting and bearing function. Other layers are stacked sequentially on the substrate 10. The stack here refers to that other layers are disposed sequentially in a thickness direction Y of the substrate 10. A plurality of layer structures may be included in the substrate 10. The specific layer structure composition of the substrate 10 is not limited in the embodiment of the present application. Moreover, the thickness direction Y of other layers located on a side of the substrate 10 is generally consistent with the thickness direction Y of the substrate 10. Therefore, for ease of description, the thickness direction Y of the substrate 10 or thickness direction Y of other layers mentioned hereinafter in the embodiment of the present application is illustrated by using the same direction.

The alignment mark 20 is disposed on a side of the substrate 10. The alignment mark 20 can provide a positioning reference. Therefore, when a subsequent layer is prepared, the position of the layer is calibrated and aligned. The specific type of a layer to be positioned by means of the alignment mark 20 is not limited in the embodiment of the present application. Illustratively, the array substrate according to the embodiment of the present application may be applicable to a display panel in which a micro light-emitting diode is used as a light-emitting source. In the process of transferring the micro light-emitting diode to the array substrate, the transfer position of the micro light-emitting diode may be determined by means of the alignment mark 20, improving transfer accuracy. Alternatively, when a layer structure such as an encapsulation structure, a protective layer, and a cover glass is prepared and formed, positioning may also be implemented by means of the alignment mark 20 to guarantee that the position of a finally-formed layer in the display panel is relatively accurate and reliable.

The specific material composition of the alignment mark 20 and the specific position of the alignment mark 20 in the array substrate are not limited in the embodiment of the present application. Illustratively, the alignment mark 20 may include a metal material and may provide a positioning reference by using the principle of metallic reflection. Further, the alignment mark 20 may be disposed in the same layer as some metal wires. That is, the alignment mark 20 and the metal wires are located at the same height in the thickness direction Y and have the same internal material composition.

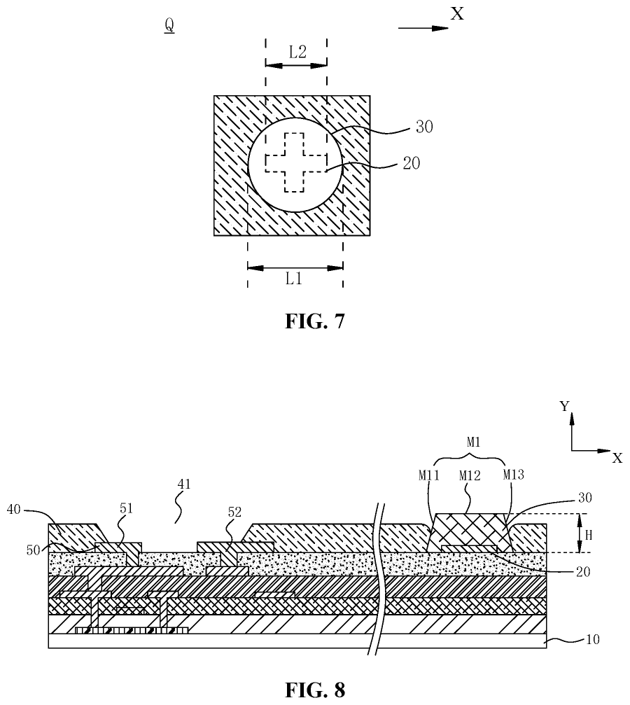

Additionally, the alignment mark 20 may have various shape structures. Optionally, an orthographic projection of the alignment mark 20 on the substrate 10 may be in a regular shape, for example, a cross, an L-shape, a T-shape, a triangle, and a prism. Alternatively, the orthographic projection of the alignment mark 20 on the substrate 10 may also be in an irregular shape. This is not limited in the embodiment of the present application. FIG. 5 illustrates the case where the orthographic projection of the alignment mark 20 on the substrate is cross-shaped. FIG. 6 illustrates the case where the orthographic projection of the alignment mark 20 on the substrate is square.

The light-shielding layer 40 includes a light-shielding material. The light-shielding layer 40 may absorb light, thereby reducing the risk of display abnormality of a subsequently-formed display panel due to problems such as a reflection of light. The specific position of the light-shielding layer 40 is not limited in the embodiment of the present application. Illustratively, the light-shielding layer 40 may also serve as a pixel defining layer. The pixel defining layer can enclose a pixel opening for accommodating a light-emitting element 60. The light-emitting element 60 includes, but is not limited to, an organic light-emitting element and a micro light-emitting diode.

In the related art, since the light-shielding layer 40 is located on the side of the alignment mark 20 facing away from the substrate 10, the light-shielding layer 40 easily covers the alignment mark 20. In this case, when the light-shielding layer 40 is formed in the patterning process of an entire light-shielding layer, a to-be-formed pattern fails to be positioned through the alignment mark. Additionally, when other layers on a side of the light-shielding layer 40 facing away from the substrate 10 are prepared, it is difficult to implement positioning by means of the alignment mark 20, thereby easily causing a preparation error and being disadvantageous to the final preparation yield.

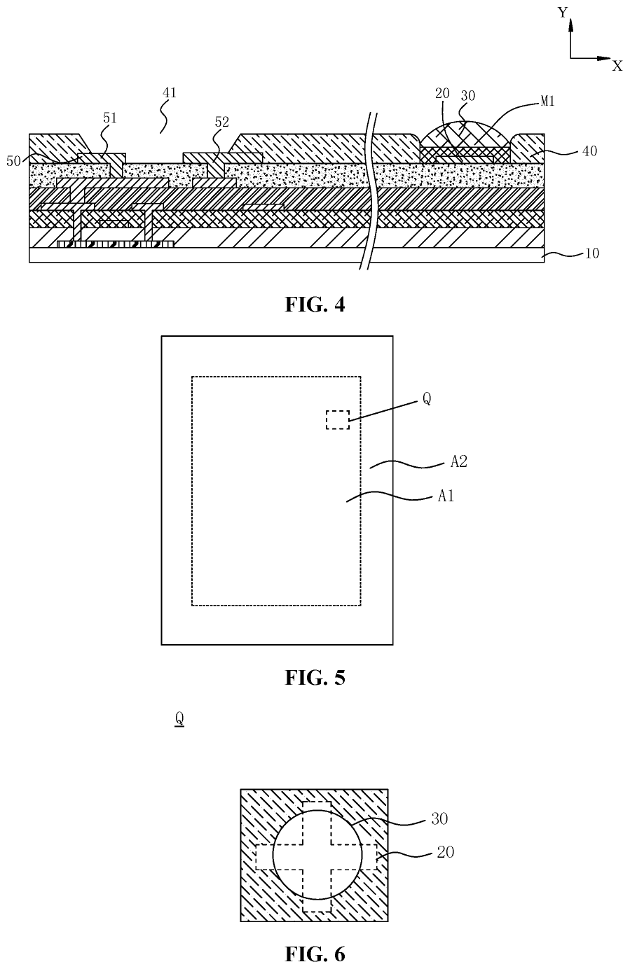

In the embodiment of the present application, the mark covering layer 30 is added. The mark covering layer 30 is disposed on the side of the alignment mark 20 facing away from the substrate 10. As shown in FIGS. 1 to 3, the mark covering layer 30 may be in contact with the alignment mark 20. Alternatively, as shown in FIG. 4, the mark covering layer 30 and the alignment mark 20 may also be spaced apart in the thickness direction Y. This is not limited in the embodiment of the present application as long as the mark covering layer 30 is at least partially located on the side of the alignment mark 20 facing away from the substrate 10.

The mark covering layer 30 at least partially overlaps the alignment mark 20. That is, as shown in FIG. 6, an orthographic projection of the mark covering layer 30 on the substrate 10 may completely covers the alignment mark 20. Alternatively, as shown in FIG. 5, the orthographic projection of the mark covering layer 30 on the substrate 10 may also merely cover a partial structure of the alignment mark 20. Moreover, the shape of the orthographic projection of the mark covering layer 30 on the substrate 10 may be the same as or different from the shape of the orthographic projection of the alignment mark 20 on the substrate 10, which is not limited in the embodiment of the present application.

The transmittance of the light-shielding layer 40 is less than the transmittance of the mark covering layer 30. Transmittance generally corresponds to the light transmittance of a layer structure. In the same light conditions, a higher transmittance indicates more light is able to be transmitted through the layer and higher corresponding brightness. The mark covering layer 30 may include a transparent material. Alternatively, the mark covering layer 30 may include a translucent material. This is not limited in the embodiment of the present application as long as the transmittance of the light-shielding layer 40 is less than the transmittance of the mark covering layer 30.

Further, the light-shielding layer 40 is in contact with the mark covering layer 30 and can expose at least a portion of the mark covering layer 30. Specifically, the mark covering layer 30 may be prepared and formed before the light-shielding layer 40. The light-shielding layer 40 may be formed by coating a light-shielding material. In this case, in the preparation process of the light-shielding layer 40, due to the limitation of factors such as the material or surface shape of the mark covering layer 30, at least part of the light-shielding material falling on a side of the mark covering layer 30 facing away from the substrate 10 may slide on a side of the mark covering layer 30 in a direction parallel to a plane where the substrate 10 is located. Therefore, the formed light-shielding layer 40 may be in contact with the mark covering layer 30 and can expose at least a portion of the mark covering layer 30.

In this case, since the mark covering layer 30 at least partially overlaps the alignment mark 20, the light-shielding layer 40 may also expose at least a partial structure of the alignment mark 20. Moreover, since the mark covering layer 30 has a relatively high transmittance, the relative position of the alignment mark 20 may also be determined through the mark covering layer 30 when a subsequent layer is prepared, thereby implementing the function of positioning, meeting preparation needs, and improving preparation accuracy.

It is to be noted that referring to FIGS. 5 and 6, the finally formed display panel may have a display region for implementing a display effect and a non-display region disposed around the periphery of the display region. The array substrate may include a first region A1 corresponding to the display region and a second region A2 corresponding to the non-display region. On this basis, the alignment mark 20 may be disposed in the first region A1 or the second region A2, which is not limited in the embodiment of the present application.

The display panel may also merely include a display region, for example, a borderless display panel. The alignment mark may be disposed in a region corresponding to the display region.

However, in the related art, in order to reduce the risk of the light-shielding layer 40 shielding the alignment mark 20, the light-shielding layer 40 may be generally formed in a manner of reducing the coating region of the light-shielding material. Moreover, the formed light-shielding layer 40 can avoid the alignment mark 20. For example, the display panel is rectangular in outline and has a size of 20 cm*20 cm. The alignment mark 20 is disposed in the non-display region. In this case, the size of the coating region corresponding to the light-shielding material needs to be narrowed. The size of the coating region may be 18 cm*18 cm. However, if the alignment mark 20 is disposed in the display region, that is, if the alignment mark 20 is located 20 in the center of the display panel, the light-shielding material can easily cover the alignment mark in different directions even if the coating region of the light-shielding material is reduced. Therefore, in the related art, it is difficult that the light-shielding material is disposed in the display region.

However, in the embodiment of the present application, due to the existence of the mark covering layer 30, the mark covering layer 30 guarantees that after the alignment mark 20 is prepared completely in the light-shielding layer 40, the alignment mark 20 may be still exposed to implement the function of positioning. In this case, the alignment mark 20 may be disposed in the first region A1 corresponding to the display region or in the second region A2 corresponding to the non-display region. Moreover, when the light-shielding layer 40 is prepared, the size of the coating region corresponding to the light-shielding material does not need to be reduced, thereby improving the covering area of the light-shielding layer 40 and meeting the actual needs of the subsequently-formed display panel.

In some embodiments, as shown in FIG. 1, the mark covering layer 30 includes a first surface M1 facing away from the substrate 10. At least a portion of the first surface M1 is inclined relative to the plane where the substrate 10 is located.

The first surface M1 is a surface of the mark covering layer 30 facing away from the substrate 10. The first surface M1 may be a structure such as a plane, a folded surface, or a curved surface or may be in another irregular shape, which is not limited in the embodiment of the present application.

The light-shielding layer 40 may be prepared after the mark covering layer 30 is formed. Part of the light-shielding material used for forming the light-shielding layer 40 may fall on the side of the mark covering layer 30 facing away from the substrate 10 in the preparation process. That is, at least part of the light-shielding material may fall on the first surface M1. In this case, if the first surface M1 is parallel to the plane where the substrate 10 is located, it is difficult for part of the light-shielding material falling on the first surface M1 to shift, thereby resulting in the gathering of the light-shielding material on the first surface M1. In severe cases, the light-shielding material may cover and shield the alignment mark 20, unable to meet the requirements for positioning a subsequent layer.

On this basis, in the embodiment of the present application, the shape of the mark covering layer 30 is controlled so that at least a portion of the first surface M1 is inclined relative to the plane where the substrate 10 is located. That is, the first surface M1 can have a certain slope. Therefore, the light-shielding material falling on the first surface M1 may move downward along the first surface M1 under factors such as the action of gravity, thereby reducing the risk of the light-shielding material gathering on the first surface M1. With this arrangement, more structures in the alignment mark 20 may be exposed from the light-shielding layer 40, meeting the positioning needs for subsequent preparation.

In some embodiments, the first surface M1 includes a curved surface. The first surface M1 may be a curved surface entirely. Alternatively, only part of the first surface M1 may be a curved surface. This is not limited in the embodiment of the present application.

A curved surface generally has a certain slope. Compared with the technical solution that the first surface M1 is configured to include an inclined surface, inclination angles of the curved surface in different positions relative to the plane where the substrate 10 is located are different. Therefore, a position where the light-shielding material easily gathers in the first surface M1 is configured to have a higher slope according to an actual situation so that the light-shielding material may move along the first surface M1 more easily and be separated from the first surface M1. Accordingly, the alignment mark 20 can be more easily exposed from the light-shielding layer 40, thereby reducing the preparation difficulty of a subsequent layer, improving preparation accuracy, and having relatively high practicability.

In some embodiments, the curved surface protrudes in a direction away from the substrate 10 and at least partially overlaps the alignment mark 20.

The curved surface has a certain slope and can protrude in the direction away from the substrate 10. In this case, when the light-shielding material falls on the curved surface, the light-shielding material may easily move downward along the slope of the curved surface, thereby making the light-shielding material difficult to gather on the curved surface.

Moreover, the curved surface at least partially overlaps the alignment mark 20. That is, an orthographic projection of the curved surface on the substrate 10 may completely cover the orthographic projection of the alignment mark 20 on the substrate 10. Alternatively, the orthographic projection of the alignment mark 20 on the substrate 10 may merely cover a partial structure of the orthographic projection of the alignment mark 20 on the substrate 10.

Such a design may reduce the probability that the light-shielding material gathers on the curved surface in the preparation process of the light-shielding layer 40, thereby further reducing the risk of the light-shielding material covering the alignment mark 20, guaranteeing that the alignment mark 20 can be more easily exposed from the light-shielding layer 40, thus reducing the preparation difficulty of a subsequent layer and improving the preparation accuracy of a subsequent layer.

Additionally, such a design enables the mark covering layer 30 to function as a convex lens to a certain degree. Therefore, the alignment mark 20 can be more easily recognized in the alignment process, thereby reducing alignment difficulty and improving alignment accuracy.

In some embodiments, referring to FIG. 8, the first surface M1 includes a first portion M11 and a second portion M12 that are disposed side by side in the direction parallel to the plane where the substrate 10 is located. The first portion M11 is inclined relative to the plane where the substrate 10 is located. The second portion M12 intersects the first portion M11.

The first surface M1 at least includes the first portion M11 and the second portion M12 that intersect each other. The first portion M11 may be inclined relative to the plane where the substrate 10 is located so that the light-shielding material falling on the first surface M1 may move along the slope of the first portion M11, thereby leaving the first surface M1. The second portion M12 may be inclined relative to the plane where the substrate 10 is located. Alternatively, the second portion M12 may be parallel to the plane where the substrate 10 is located. This is not limited in the embodiment of the present application.

In some optional embodiments, the second portion M12 is parallel to the plane where the substrate 10 is located. That is, the sectional shape of the mark covering layer 30 may be in a trapezoidal structure. Further, the first surface M1 includes a third portion M13 located on a side of the second portion M12 facing away from the first portion M11. The third portion M13 may be symmetrical with the first portion M11 in the thickness direction Y so that the sectional shape of the mark covering layer 30 may be in the structure of an isosceles trapezoid.

In the embodiment of the present application, the first portion M11 in the first surface M1 is inclined relative to the plane where the substrate 10 is located. Therefore, in the preparation process of the light-shielding layer 40, the light-shielding material may move along the slope of the first portion M11, thereby reducing the risk of the light-shielding material gathering on the first surface M1, further guaranteeing that the alignment mark 20 can be more easily exposed from the light-shielding layer 40, and meeting positioning needs.

In some embodiments, the mark covering layer 30 includes a hydrophobic material.

Hydrophobic materials refer to a kind of low surface-energy materials with contact angles of static liquids on smooth surfaces greater than 90. The hydrophobic materials usually have important characteristics such as water resistance, anti-fog, snow defense, anti-pollution, anti-adhesion, anti-oxidation, anti-corrosion, self-cleaning, and anti-conduction.

On this basis, in the embodiment of the present application, the mark covering layer 30 includes the hydrophobic material so that the first surface M1 on the mark covering layer 30 is relatively smooth. Therefore, in the preparation process of the light-shielding layer 40, the light-shielding material can slide from the first surface M1 more easily, thereby reducing the probability that the light-shielding layer 40 covers the mark covering layer 30, thus guaranteeing that the alignment mark 20 can be exposed from the light-shielding layer 40, and meeting alignment needs.

Of course, in some other embodiments, the surface of the mark covering layer 30 facing away from the substrate 10 may also be formed through a hydrophobic treatment.

The hydrophobic treatment refers to transforming the surface of an object into a hydrophobic surface so that liquids do not easily gather on the surface, thereby reducing the probability that the surface is wetted by the liquids. On this basis, in the embodiment of the present application, the first surface M1 is provided with the hydrophobic treatment so that the light-shielding material can slide from the first surface M1 more easily, reducing the risk of the light-shielding material gathering on the first surface M1 and meeting actual needs.

It is to be noted that in the embodiment of the present application, the mark covering layer 30 may include the hydrophobic material and the first surface M1 is provided with the hydrophobic treatment, thereby further improving the hydrophobic performance of the first surface M1 and reducing the risk of the light-shielding material gathering on the first surface M1. Moreover, in the embodiment of the present application, since the first surface M1 has a certain hydrophobic property, at least a portion of the first surface M1 may be inclined relative to the plane where the substrate 10 is located. Alternatively, the first surface M1 may be completely parallel to the plane where the substrate 10 is located. This is not limited in the embodiment of the present application.

In some embodiments, the maximum height of the mark covering layer 30 is not less than the height of the light-shielding layer 40 in the thickness direction Y of the substrate 10. That is, the mark covering layer 30 may partially exceed the light-shielding layer 40 in the thickness direction Y of the substrate 10; alternatively, a partial structure of the mark covering layer 30 may be flush with the light-shielding layer 40 in the thickness direction Y of the substrate 10.

In general, in the case where the size of the light-shielding layer 40 is unchanged, the smaller the size of the mark covering layer 30 in the thickness direction Y is, the more easily the light-shielding material covers the mark covering layer 30. If the maximum height of the mark covering layer 30 is less than the height of the light-shielding layer 40 in the thickness direction Y, the light-shielding material may easily cover and shield the mark covering layer 30 completely in the preparation process of the light-shielding layer 40, thereby making the alignment mark 20 unable to be exposed from the light-shielding layer 40 and easily causing problems such as the alignment difficulty of a subsequent layer.

In the embodiment of the present application, the arrangement in which the maximum height of the mark covering layer 30 is not less than the height of the light-shielding layer 40 guarantees that the mark covering layer 30 can have a certain height in the thickness direction Y, thereby helping the light-shielding material slip from the mark covering layer 30. Moreover, the probability that the light-shielding layer 40 covers the mark covering layer 30 completely is reduced so as to guarantee that the alignment mark 20 can be exposed from the light-shielding layer 40, contributing to meeting alignment needs in the subsequent preparation process.

In some embodiments, as shown in FIG. 8, the maximum height of the mark covering layer 30 is H. H satisfies that 1 μm≤H≤20 μm. Illustratively, H is one of 1 μm, 2 μm, 5 μm, 10 μm, 15 μm, or 20 μm.

It can be seen from the preceding content that the less the maximum height H of the mark covering layer 30 is, the more easily the light-shielding material covers the mark covering layer 30, thereby easily causing the risk that the alignment mark 20 cannot be exposed from the light-shielding layer 40. Therefore, in the embodiment of the present application, the maximum height H of the mark covering layer 30 is not less than 1 μm so as to guarantee that the alignment mark 20 can be exposed from the light-shielding layer 40.

If the maximum height H of the mark covering layer 30 is excessively great, some positions of the array substrate may be uneven, thereby being disadvantageous to the preparation of a subsequent layer structure. Moreover, it is easy to make the overall thickness of the finally-formed display panel excessively great, which is disadvantageous to the hand feeling in use. Therefore, in the embodiment of the present application, the maximum height H of the mark covering layer 30 is set to be greater than 20 μm, thereby helping improve the flatness of the layer and reducing the risk that the thickness of the finally-formed display panel is excessively great.

In some embodiments, as shown in FIGS. 1 and 7, the orthographic projection of the mark covering layer 30 on the substrate 10 covers the orthographic projection of the alignment mark 20 on the substrate 10.

The mark covering layer 30 may completely cover the alignment mark 20. Here the orthographic projection of the mark covering layer 30 on the substrate 10 may completely coincide with the orthographic projection of the alignment mark 20 on the substrate 10. Alternatively, the orthographic projection of the mark covering layer 30 on the substrate 10 may be partially located outside the orthographic projection of the alignment mark 20 on the substrate 10. This is not limited in the embodiment of the present application.

It is to be noted that when the orthographic projection of the mark covering layer 30 on the substrate 10 completely coincides with the orthographic projection of the alignment mark 20 on the substrate 10, processes like etching may be adopted to make the size and shape of the mark covering layer 30 be consistent with and coincide with the size and shape of the alignment mark 20.

In the embodiment of the present application, the orthographic projection of the mark covering layer 30 on the substrate 10 covers the orthographic projection of the alignment mark 20 on the substrate 10. Therefore, after the preparation of the light-shielding layer 40 is completed, part or all of the structures in the alignment mark 20 can be exposed from the light-shielding layer 40, helping further improve the alignment accuracy of a subsequent layer structure and improving the preparation yield of the finally-formed display panel.

In some embodiments, as shown in FIG. 1, the mark covering layer 30 at least partially exceeds the alignment mark 20 in a first direction X so that the mark covering layer 30 can cover a sidewall B of the alignment mark 20 in the first direction X.

The first direction X may be a direction parallel to the plane where the substrate 10 is located. The orthographic projection of the mark covering layer 30 on the substrate 10 is at least partially located outside the orthographic projection of the alignment mark 20 on the substrate 10. Moreover, the mark covering layer 30 can cover the sidewall B of the alignment mark 20 in the first direction X. The shape of the orthographic projection of the mark covering layer 30 on the substrate 10 may be the same as or different from the shape of the orthographic projection of the alignment mark 20 on the substrate 10, which is not limited in the embodiment of the present application.

In the embodiment of the present application, the mark covering layer 30 at least partially exceeds the alignment mark 20. Therefore, the mark covering layer 30 may better cover the alignment mark 20 so as to increase the size of the alignment mark 20 exposed relative to the light-shielding layer 40 and reduce the alignment difficulty of a subsequent layer after the preparation of the light-shielding layer 40 is completed. Moreover, the mark covering layer 30 can cover the sidewall B of the alignment mark 20 in the first direction X so that the mark covering layer 30 may also separate the sidewall B from the external environment, thereby reducing the risk of the oxidative denaturation of the alignment mark 20 and guaranteeing the reliability of the use of the alignment mark 20.

In some embodiments, as shown in FIG. 1, the size of the mark covering layer 30 in the first direction is L1. The size of the alignment mark 20 in the first direction is L2. L1 and L2 satisfy that L1≥1.2*L2.

The greater the size of the mark covering layer 30 exceeding the alignment mark 20 in the first direction X, the higher the probability of the alignment mark 20 completely exposed from the light-shielding layer 40 in the first direction X. Therefore, in the embodiment of the present application, L1 is set to be not less than 1.2*L2 so as to improve the probability of the alignment mark 20 completely exposed in the first direction X, improving the alignment reliability when a subsequent layer is prepared.

It is to be noted that in addition to the first direction X, the mark covering layer 30 may also exceed the alignment mark 20 in other directions parallel to the plane where the substrate 10 is located, thereby further increasing the size of the alignment mark 20 exposed from the light-shielding layer 40 and meeting preparation needs.

In some embodiments, the mark covering layer 30 is in contact with the alignment mark 20.

In the embodiment of the present application, no other layer exists between the mark covering layer 30 and the alignment mark 20 so as to reduce the risk of an excessively low transmittance in the position of the alignment mark 20 due to another layer, thereby helping reduce the alignment mark 20 when a subsequent layer is prepared and improving alignment accuracy. Moreover, when the mark covering layer 30 is prepared, the mark covering layer 30 is relatively close to the alignment mark 20. Therefore, it guarantees that the prepared mark covering layer 30 can overlap the alignment mark 20, reducing preparation difficulty.

It is to be noted that the specific layer position of the mark covering layer 30 and the specific layer position of the alignment mark 20 are not limited in the embodiment of the present application.

In some embodiments, as shown in FIG. 1, the array substrate further includes a first conductive portion 51 disposed on a side of the substrate 10. The first conductive portion 51 is used for transmitting a first power signal. The first conductive portion 51 and the alignment mark 20 include the same material and are located in the same layer.

The first conductive portion 51 is used for transmitting the first power signal. Illustratively, the first power signal is transmitted to the light-emitting element 60 to drive the light-emitting element 60 to emit light and perform display. The first conductive portion 51 may include a metal material.

On this basis, in the embodiment of the present application, the alignment mark 20 and the first conductive portion 51 are disposed in the same layer and include the same material. Therefore, the first conductive portion 51 and the alignment mark 20 are enabled to be prepared and formed in the same preparation process by using the same material while the light reflection and alignment needs of the alignment mark 20 are met, thereby improving preparation efficiency and reducing the required preparation costs.

It is to be noted that the alignment mark 20 needs to be insulated from the first conductive portion 51. That is, the first power signal is not transmitted in the alignment mark 20. No signal may be transmitted in the alignment mark 20. Alternatively, the alignment mark 20 may be also used for transmitting a specified signal other than the first power signal. This is not limited in the embodiment of the present application.

In some embodiments, as shown in FIGS. 6 and 7, the shape of the orthographic projection of the alignment mark 20 on the substrate 10 is different from the shape of the orthographic projection of the mark covering layer 30 on the substrate 10.

In the embodiment of the present application, the shape of the orthographic projection of the alignment mark 20 on the substrate 10 may be different from the shape of the orthographic projection of the mark covering layer 30 on the substrate 10. Therefore, the mark covering layer 30 does not need to be formed through etching. The mark covering layer 30 may be formed through coating, dripping or the like so as to reduce the preparation difficulty of the mark covering layer 30 and improve preparation efficiency.

The shape of the orthographic projection of the mark covering layer 30 on the substrate 10 is not limited in the embodiment of the present application. Illustratively, the orthographic projection of the mark covering layer 30 on the substrate 10 may be circular, square, or in other regular shapes. Alternatively, the orthographic projection of the mark covering layer 30 on the substrate 10 may be in an irregular shape.

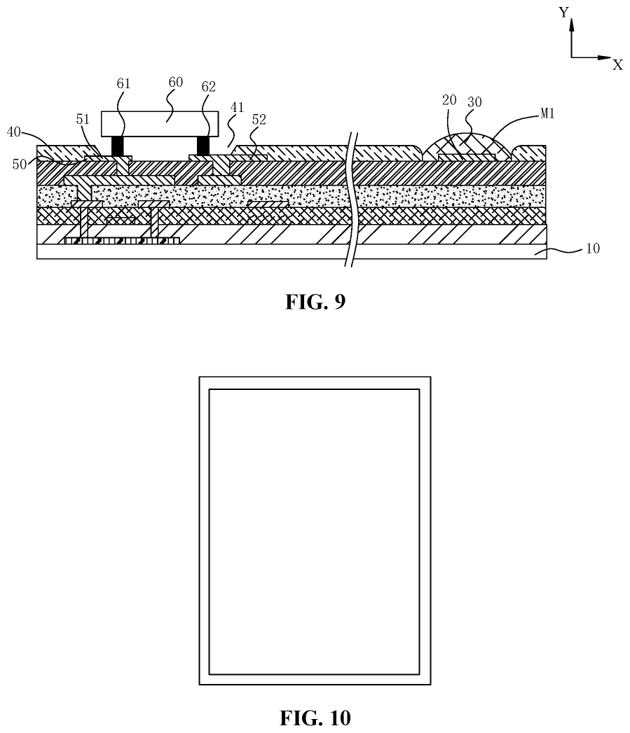

In a second aspect, referring to FIG. 9, an embodiment of the present application provides a display panel. The display panel includes the array substrate in any preceding embodiment.

The display panel according to the embodiment of the present application has the beneficial effects of the array substrate in any preceding embodiment of the present application. The specific content may be referred to the preceding description about the beneficial effects of the array substrate and is not repeated in the embodiment of the present application.

In some embodiments, the display panel further includes a light-emitting element 60. A light-shielding layer 40 is provided with an opening structure 41. The light-emitting element 60 is disposed in the opening structure 41 and includes a first electrode 61 and a second electrode 62 that face a side of a substrate 10.

The array substrate includes a first metal layer 50. The first metal layer 50 includes a first conductive portion 51 and a second conductive portion 52 that are insulated from each other. The first conductive portion 51 and the second conductive portion 52 are at least partially exposed from the opening structure 41 so that the first electrode 61 and the second electrode 62 are electrically connected to the first conductive portion 51 and the second conductive portion 52 respectively.

The light-emitting element 60 is a main component used for implementing the display effect in the display panel. Illustratively, the light-emitting element 60 may be a micro light-emitting diode. The light-emitting element 60 includes the first electrode 61 and the second electrode 62. The first electrode 61 and the second electrode 62 are used for receiving different power signals to meet the light-emitting needs of the light-emitting element 60.

On this basis, the array substrate is provided with the first metal layer 50. The first metal layer 50 may be a metal layer closest to the light-emitting element 60. The first metal layer 50 includes the first conductive portion 51 and the second conductive portion 52 that are insulated from each other. The first conductive portion 51 is used for transmitting a signal to the first electrode 61. The second conductive portion 52 is used for transmitting a signal to the second electrode 62.

On this basis, in the embodiment of the present application, the first conductive portion 51 and the second conductive portion 52 are at least partially exposed from the opening structure 41 to meet the needs for the electrical connection of the first conductive portion 51 and the first electrode 61 and the needs for the electrical connection of the second conductive portion 52 and the second electrode 62. Optionally, the light-shielding layer 40 may cover a partial structure of the first conductive portion 51, and the opening structure 41 may also expose a partial structure of the first conductive portion 51. Similarly, the light-shielding layer 40 may cover a partial structure of the second conductive portion 52, and the opening structure 41 may also expose a partial structure of the second conductive portion 52.

The array substrate according to the embodiment of the present application may be applicable to a display panel in which a structure like a micro light-emitting diode is used as a light-emitting element 60. Moreover, in the process of transferring the light-emitting element 60 to the array substrate, a positioning reference may be made by means of an alignment mark 20, guaranteeing the connection reliability between the light-emitting element 60 and the first conductive portion 51 and the connection reliability between the light-emitting element 60 and the second conductive portion 52.

In some optional embodiments, the alignment mark 20 may be located in the first metal layer 50. Moreover, the alignment mark 20 and the first conductive portion 51 include the same material. That is, the alignment mark 20 and the first conductive portion 51 use the same material and are formed together in the same preparation process so as to improve preparation efficiency and reduce preparation costs.

In a third aspect, referring to FIG. 10, an embodiment of the present application provides a display device. The display device includes the display panel in any preceding embodiment.

The display device according to the embodiment of the present application has the beneficial effects of the display panel in any preceding embodiment of the present application. The specific content may be referred to the preceding description about the beneficial effects of the display panel and is not repeated in the embodiment of the present application.

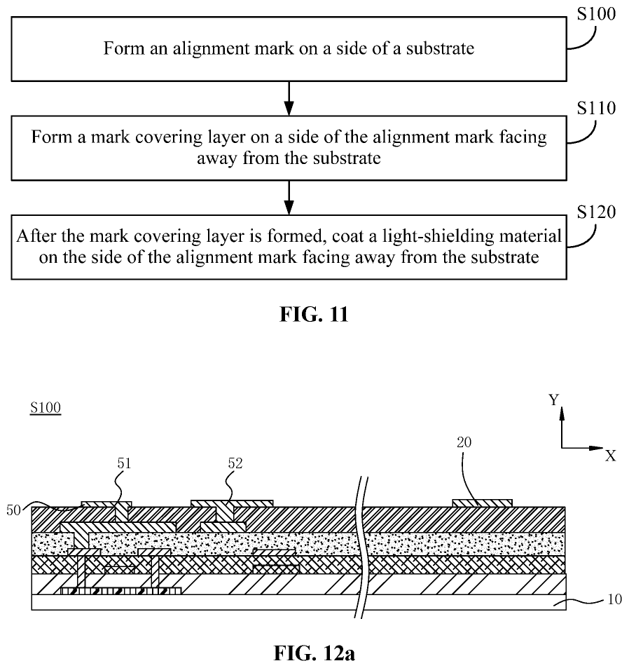

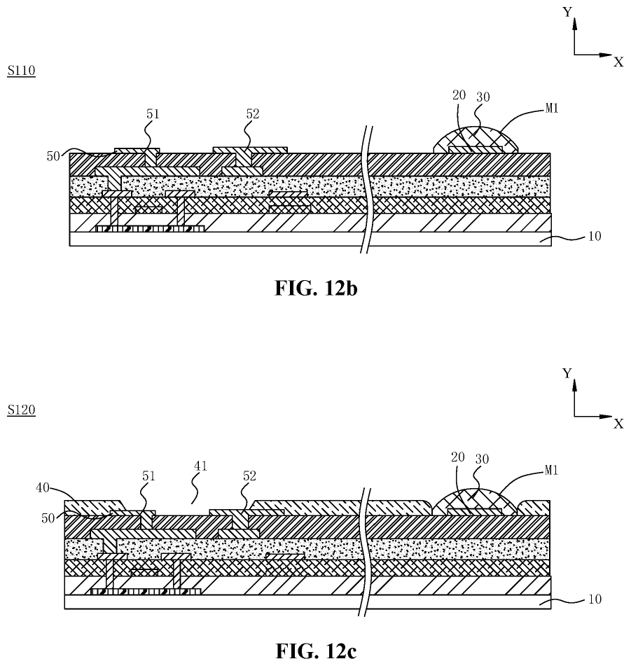

In a fourth aspect, referring to FIGS. 11 and 12, an embodiment of the present application provides a preparation method of an array substrate. The method includes the steps below.

In S100, an alignment mark is formed on a side of a substrate.

Referring to FIG. 12a, in step S100, the alignment mark 20 is formed on a side of the substrate 10. The specific position of the alignment mark 20 is not limited in the embodiment of the present application. Optionally, the alignment mark 20 and a first conductive portion 51 may be formed in the same preparation process and are insulated from each other. The first conductive portion 51 is used for transmitting a first power signal.

In S110, a mark covering layer is formed on a side of the alignment mark facing away from the substrate.

Referring to FIG. 12b, in step S110, the mark covering layer 30 at least partially overlaps the alignment mark 20. That is, an orthographic projection of the mark covering layer 30 on the substrate 10 may completely covers the alignment mark 20. Alternatively, the orthographic projection of the mark covering layer 30 on the substrate 10 may also merely cover a partial structure of the alignment mark 20. The mark covering layer 30 may be in contact with the alignment mark 20. Alternatively, the mark covering layer 30 and the alignment mark 20 may also be spaced apart in a thickness direction Y.

The mark covering layer 30 may include a transparent material or a translucent material. That is, the mark covering layer 30 has a certain transmittance. Therefore, when some layers are prepared, the alignment mark 20 may be recognized through the mark covering layer 30 to implement layer positioning and improve preparation accuracy.

In S120, after the mark covering layer is formed, a light-shielding material is coated on the side of the alignment mark facing away from the substrate.

Referring to FIG. 12c, in step S120, due to the limitation of factors such as the material or surface shape of the mark covering layer 30, at least part of the light-shielding material falling on a side of the mark covering layer 30 facing away from the substrate 10 may slide on a side of the mark covering layer 30 in a direction parallel to a plane where the substrate 10 is located. Therefore, the light-shielding material can be in contact with the mark covering layer 30, expose at least a portion of the mark covering layer 30, and form a light-shielding layer 40.

In the embodiment of the present application, since the mark covering layer 30 at least partially overlaps the alignment mark 20, the light-shielding layer 40 may also expose at least a partial structure of the alignment mark 20. Moreover, since the mark covering layer 30 has a relatively high transmittance, the relative position of the alignment mark 20 may also be determined through the mark covering layer 30 when a subsequent layer is prepared, thereby implementing the function of positioning, meeting preparation needs, and improving preparation accuracy.

In some embodiments, in step S110, a surface of the mark covering layer 30 facing away from the substrate 10 is formed through a hydrophobic treatment.

The hydrophobic treatment refers to transforming the surface of an object into a hydrophobic surface so that liquids do not easily gather on the surface, thereby reducing the probability that the surface is wetted by liquids.

On this basis, the mark covering layer 30 has a first surface M1 facing away from the substrate 10. The first surface M1 is provided with the hydrophobic treatment so that the light-shielding material can slide from the first surface M1 more easily, reducing the risk of the light-shielding material gathering on the first surface M1, further enabling the light-shielding layer 40 to expose at least a partial structure of the alignment mark 20, and meeting alignment needs.

In some embodiments, in step S110, a hydrophobic material is disposed on the side of the alignment mark 20 facing away from the substrate 10 through coating or dripping so as to form the mark covering layer 30.

In the embodiment of the present application, the mark covering layer 30 may be formed through coating or dripping. In this case, the shape of the orthographic projection of the mark covering layer 30 on the substrate 10 may be different from the shape of an orthographic projection of the alignment mark 20 on the substrate 10, thereby reducing the preparation difficulty of the mark covering layer 30.

Moreover, the mark covering layer 30 is composed of the hydrophobic material. Hydrophobic materials refer to a kind of low surface-energy materials with contact angles of static liquids on smooth surfaces greater than 90. The hydrophobic materials usually have important characteristics such as water resistance, anti-fog, snow defense, anti-pollution, anti-adhesion, anti-oxidation, anti-corrosion, self-cleaning, and anti-conduction.

Such a design enables the first surface M1 on the mark covering layer 30 to be relatively smooth. Therefore, in the preparation process of the light-shielding layer 40, the light-shielding material can slide from the first surface M1 more easily, thereby reducing the probability that the light-shielding layer 40 covers the mark covering layer 30, thus guaranteeing that the alignment mark 20 can be exposed from the light-shielding layer 40, and meeting alignment needs.

Although the embodiments disclosed by the present application are as described above, the content thereof is merely embodiments for facilitating the understanding of the present application and is not intended to limit the present application. Any technical person skilled in the art to which the present application pertains may make any modifications and variations in the implementation forms and details without departing from the spirit and scope disclosed by the present application, but the protection scope of the present application is still subject to the scope defined by the appended claims.

The preceding are only specific embodiments of the present application. Those skilled in the art may clearly understand that for ease and conciseness of description, for the replacement of other connection modes described above and the like, reference may be made to corresponding procedures in the preceding method embodiments and is not repeated here. It is to be understood that the specific embodiments are not intended to limit the present application. Those skilled in the art may easily conceive various equivalent modifications or substitutions within the technical scope of the present application. These modifications or substitutions should fall within the scope of the present application.

What is claimed is:

1. An array substrate, comprising:
a substrate;
an alignment mark disposed on a side of the substrate;
a mark covering layer disposed on a side of the alignment mark facing away from the substrate, wherein the mark covering layer at least partially overlaps the alignment mark; and
a light-shielding layer, wherein a transmittance of the light-shielding layer is less than a transmittance of the mark covering layer, and the light-shielding layer is in contact with the mark covering layer and exposes at least a portion of the mark covering layer.

2. The array substrate according to claim 1, wherein the mark covering layer comprises a first surface facing away from the substrate, and at least a portion of the first surface is inclined relative to a plane where the substrate is located.

3. The array substrate according to claim 2, wherein the first surface comprises a curved surface.

4. The array substrate according to claim 3, wherein the curved surface protrudes in a direction away from the substrate and at least partially overlaps the alignment mark.

5. The array substrate according to claim 2, wherein the first surface comprises a first portion and a second portion that are disposed side by side in a direction parallel to the plane where the substrate is located, the first portion is inclined relative to the plane where the substrate is located, and the second portion intersects the first portion.

6. The array substrate according to claim 1, wherein the mark covering layer satisfies at least one of:
the mark covering layer comprises a hydrophobic material; or
a surface of the mark covering layer facing away from the substrate is formed through a hydrophobic treatment.

7. The array substrate according to claim 1, wherein a maximum height of the mark covering layer is not less than a height of the light-shielding layer in a thickness direction of the substrate.

8. The array substrate according to claim 7, wherein the maximum height of the mark covering layer is H, and H satisfies that 1 μm≤H≤20 μm.

9. The array substrate according to claim 1, wherein an orthographic projection of the mark covering layer on the substrate covers an orthographic projection of the alignment mark on the substrate.

10. The array substrate according to claim 9, wherein the mark covering layer at least partially exceeds the alignment mark in a first direction so that the mark covering layer covers a sidewall of the alignment mark in the first direction.

11. The array substrate according to claim 10, wherein a size of the mark covering layer in the first direction is L1, and a size of the alignment mark in the first direction is L2,
wherein L1 and L2 satisfy that L1≥1.2*L2.

12. The array substrate according to claim 1, wherein the mark covering layer is in contact with the alignment mark.

13. The array substrate according to claim 1, further comprising a first conductive portion disposed on a side of the substrate, wherein the first conductive portion is used for transmitting a first power signal, and the first conductive portion and the alignment mark comprise a same material and are located in a same layer.

14. The array substrate according to claim 1, wherein a shape of an orthographic projection of the alignment mark on the substrate is different from a shape of an orthographic projection of the mark covering layer on the substrate.

15. A display panel, comprising an array substrate,
wherein the array substrate comprises:
a substrate;
an alignment mark disposed on a side of the substrate;
a mark covering layer disposed on a side of the alignment mark facing away from the substrate, wherein the mark covering layer at least partially overlaps the alignment mark; and
a light-shielding layer, wherein a transmittance of the light-shielding layer is less than a transmittance of the mark covering layer, and the light-shielding layer is in contact with the mark covering layer and exposes at least a portion of the mark covering layer.

16. The display panel according to claim 15, further comprising a light-emitting element, wherein the light-shielding layer is provided with an opening structure, and the light-emitting element is disposed in the opening structure and comprises a first electrode and a second electrode both facing the substrate,
wherein the array substrate comprises a first metal layer, the first metal layer comprises a first conductive portion and a second conductive portion that are insulated from each other, and the first conductive portion and the second conductive portion are at least partially exposed from the opening structure so that the first electrode and the second electrode are electrically connected to the first conductive portion and the second conductive portion respectively.

17. A display device, comprising the display panel according to claim 15.

18. A preparation method of an array substrate, comprising:
forming an alignment mark on a side of a substrate;
forming a mark covering layer on a side of the alignment mark facing away from the substrate, wherein the mark covering layer at least partially overlaps the alignment mark; and
after the mark covering layer is formed, coating a light-shielding material on the side of the alignment mark facing away from the substrate, wherein the light-shielding material is in contact with the mark covering layer, exposes at least a portion of the mark covering layer, and forms a light-shielding layer.

19. The preparation method according to claim 18, wherein forming the mark covering layer on the side of the alignment mark facing away from the substrate comprises: performing hydrophobic treatment on a surface of the mark covering layer facing away from the substrate.

20. The preparation method according to claim 18, wherein forming the mark covering layer on the side of the alignment mark facing away from the substrate comprises: disposing a hydrophobic material on the side of the alignment mark facing away from the substrate through coating or dripping to form the mark covering layer.
